(19) United States
(12) Patent Application Publication
(10) Pub. No.: US 2002/0121386 A1
(43) Pub. Date: Sep. 5, 2002

(54) Ventilated enclosure apparatus

(75) Inventors: Bernie Traut, Buffalo, MN (US); Harold Lakoduk, Anoka, MN (US); David Brouillard, Monticello, MN (US)

Correspondence Address: Merchant & Gould P.C., P.O. Box 2903, Minneapolis, MN, 55402-0903, US

(73) Assignee: Hoffman Enclosures, Inc.

(21) Appl. No.: 09/796,694

(22) Filed: Mar. 1, 2001

(51) Int. Cl. H05K 9/00

(52) U.S. Cl. 174/35 R

(57) ABSTRACT

A double walled solar shielding system for an electrical enclosure includes an inner enclosure defining a substantially rectangular box with an inner door pivotally mounted to the inner enclosure. A shielding layer extends around the top, rear and lateral sides of the enclosure with a shielding door mounted coaxially with the inner door and having an outer layer spaced apart from the inner door. The doors open independently and may have different security measures. The system includes modular elements and may be retrofitted to existing enclosures.

### BACKGROUND OF THE INVENTION

1. Field of the Invention

The present invention relates to a solar shield system for an outdoor electrical enclosure, and in particular to a solar shield providing ventilation that may be retrofitted to existing electrical enclosures.

2. Prior Art

Electrical enclosures are often placed in remote outdoor environments to house electronics and other components within the enclosure. Often, such enclosures are mounted on a pole and are accessed periodically for servicing the internal components, reading meters and other gauges, and for other monitoring and maintenance, as may be needed. The boxes normally require some security measures and may require more than one level of security depending on the access needs of different persons. Some of these enclosure boxes may require security only to allow gauges to be read, which may be possible by looking through a transparent door or other view port. Still others require additional security providing controlled access to internal components for servicing.

The enclosures must also provide protection from the elements. The enclosure should protect components from wind and rain while maintaining durability. Such enclosures should also prevent insects, rodents and other pests from gaining access to the equipment housed in the enclosure.

Components that are typically placed in the enclosure may be heat sensitive. Therefore, it may be necessary to provide some solar shielding and ventilation for cooling to prevent overheating. As the enclosures are often very remote, servicing of active cooling systems using fans, circulating cooling fluids, or other systems may be difficult. Moreover, the cost of an active cooling system for large numbers of such enclosures may be prohibitive. Therefore, a passive cooling system is often desired that utilizes natural ventilation between double walls.

Heretofore, there has not been an enclosure providing sufficient solar shielding and security. The typical approach to address the problem has been to design a box within a box. Although such a design does provide shielding and may provide some security, the design usually shields all sides, including the bottom, where solar shielding is unnecessary, and is over-designed for the needs of a typical enclosure. Such designs often fall short in providing doors that open with a sufficient range to provide full access. Moreover, such designs typically cannot be retrofitted to existing enclosures.

Problems have also been encountered with sealed enclosures due to wear on the gasket from rubbing against another surface during opening and closing of the door, commonly know as “swiping.” Providing a good seal while avoiding swiping becomes a greater challenge when multiple access doors to a single opening are utilized.

It can be seen then that a new and improved electrical enclosure with solar shielding is needed. Such an enclosure should provide protection from the elements and a degree of passive cooling for the interior of the enclosure. Such a shielding system should provide double walled construction and provide for retrofitting to existing enclosures. In addition, it is preferable to provide security measures for accessing the interior of the enclosure through a double layer door. The present invention addresses these problems, as well as others associated with outdoor solar-shielded electrical enclosures.

### SUMMARY OF THE INVENTION

The present invention is directed to solar shield systems for electrical enclosures that are typically placed outside and exposed to the elements. The shielding system provides a double-walled shield that allows cooling air to circulate between the outer wall and inner wall. The shielding elements cover the front, back, sides and top to protect an inner enclosure from sun and provide passive cooling for the inner enclosure. The outer shielding elements each cover only one side or the door of the inner enclosure so that shielding can be retrofitted to existing enclosures. Therefore, the various shielding elements may be mixed and matched so that the present system may be used with enclosures of different sizes.

Various shielding elements are fitted together and overlap so that shielding surrounds all sides except the bottom of the enclosure. The present invention also includes a shielding element over the door of the inner enclosure. In a preferred embodiment, the door cover pivots about the same hinge as inner enclosure door for improved access and ease of providing security measures. The inner door and outer cover include one or more latches with various security measures, such as tool actuation or a key actuated latch. Different levels of security may be utilized to provide access to different persons at different levels and also provides for different degrees of access, such as access only to viewing the inner door or access to the interior of the inner enclosure. For example, a first key or tool may be needed to open the outer door, while a second key or tool may be necessary to open the inner door, thereby creating different security levels for different levels of access. The door system also is spaced apart from the inner enclosure to prevent portions of either of the doors from swiping other elements and for an improved range of motion so that the entire interior enclosure may be easily accessed without interruption from the door.

These features of novelty and various other advantages, which characterize the invention, are pointed out with particularity in the claims annexed hereto and forming a part hereof. However, for a better understanding of the invention, its advantages, and the objects obtained by its use, reference should be made to the drawings which form a further part hereof, and to the accompanying descriptive matter, in which there is illustrated and described a preferred embodiment of the invention.

### BRIEF DESCRIPTION OF THE DRAWINGS

Referring now to the drawings, wherein likes reference numerals and letters indicate corresponding structure throughout the several views:

FIG. 1 shows a front elevational view of a first embodiment of a shielded enclosure apparatus according to the principles of the present invention;

FIG. 2 shows a side elevational view of the shielded enclosure apparatus shown in FIG. 1;

FIG. 3 shows a rear elevational view of the shielded enclosure apparatus shown in FIG. 1;

FIG. 4 shows a top sectional view, take along line 4-4 of FIG. 3;

FIG. 5 shows a bottom plan view of the shielded enclosure apparatus shown in FIG. 1, with the doors in an open position;

FIG. 6 shows a front perspective view of an inner enclosure for a second embodiment of a solar-shielded enclosure, according to the principles of the present invention;

FIG. 7 shows a right side elevational view of the inner enclosure shown in FIG. 6;

FIG. 8 shows a front elevational view of the inner enclosure shown in FIG. 6 with an inner door mounted to the inner enclosure;

FIG. 9 shows a top sectional view of the inner enclosure shown in FIG. 6 with solar shielding mounted to the front, sides and rear of the inner enclosure;

FIG. 10 shows a top plan view of the outer door shielding for the shielded enclosure shown in FIG. 6;

FIG. 11 shows a top plan view of the inner enclosure shielding for the solar-shielded enclosure shown in FIG. 6;

FIG. 12 shows front elevational view of a third embodiment of a solar-shielded enclosure according to the principles of the present invention;

FIG. 13 shows a side elevational view of the solar-shielded enclosure shown in FIG. 12; and

FIG. 14 shows a bottom plan view of the enclosure shown in FIG. 12.

### DETAILED DESCRIPTION OF THE PREFERRED EMBODIMENTS

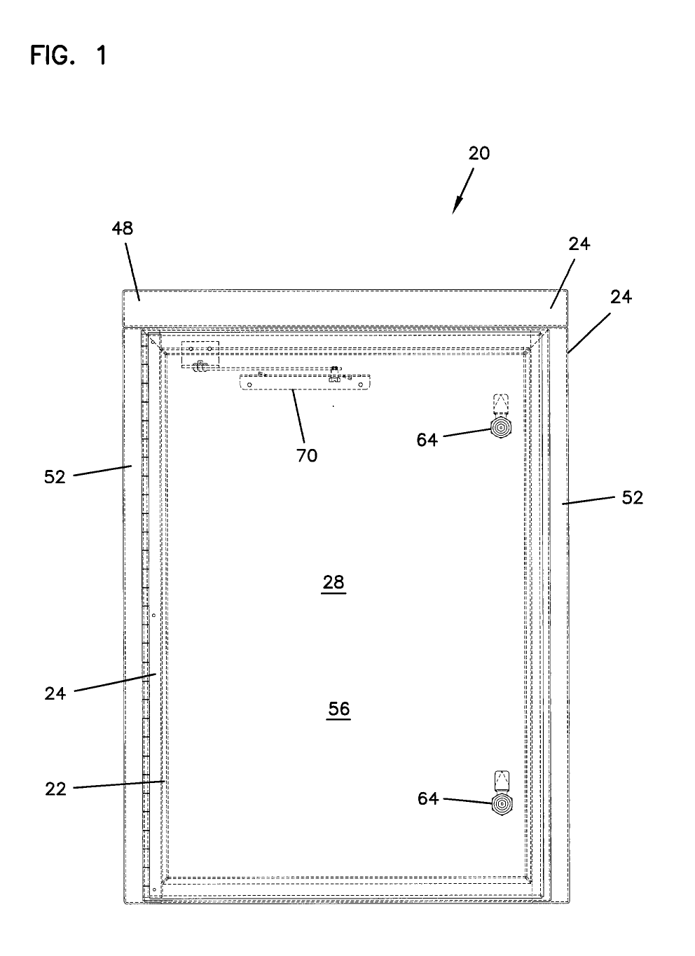

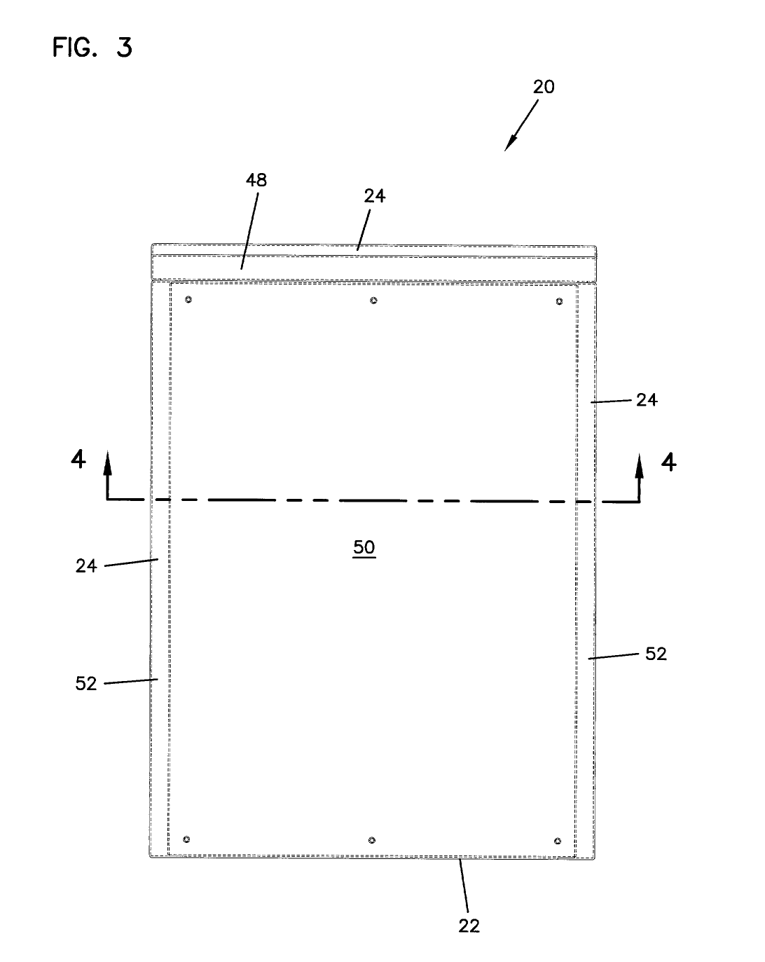

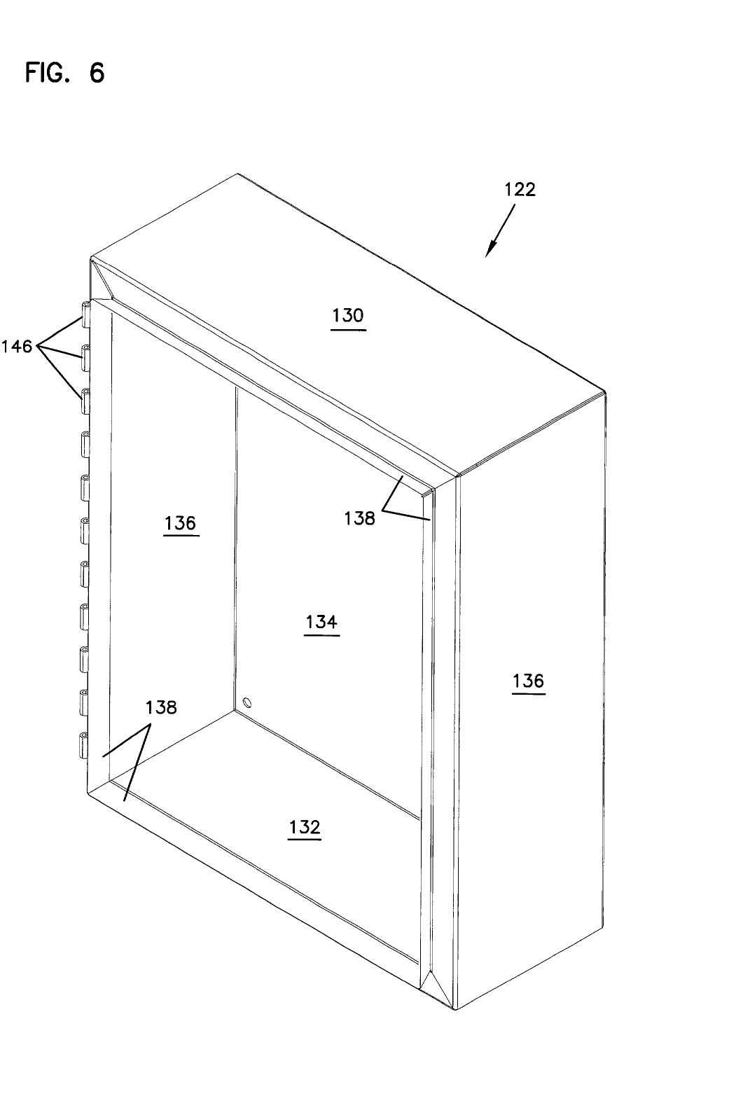

Referring now to the drawings, and in particular to FIGS. 1-3, there is shown a first embodiment of a solar-shielded enclosure, generally designated 20. The shielded enclosure 20 includes an inner enclosure 22. The inner enclosure 22 forms a protective inner compartment defining an opening configured for receiving a door assembly 28. The inner enclosure 22 is typically sealed to keep dust and/or water out and may include electromagnetic shielding. The inner enclosure 22 is sized for the needs of each application, but may be similar to a typical electrical enclosure 122, shown in FIG. 6. The enclosure 122 includes a top 130, bottom 132, sides 136, and a rear 134. In addition, an angled lip 138 extends around the opening to aid in sealing and closing to provide improved protection for the internal components housed therein.

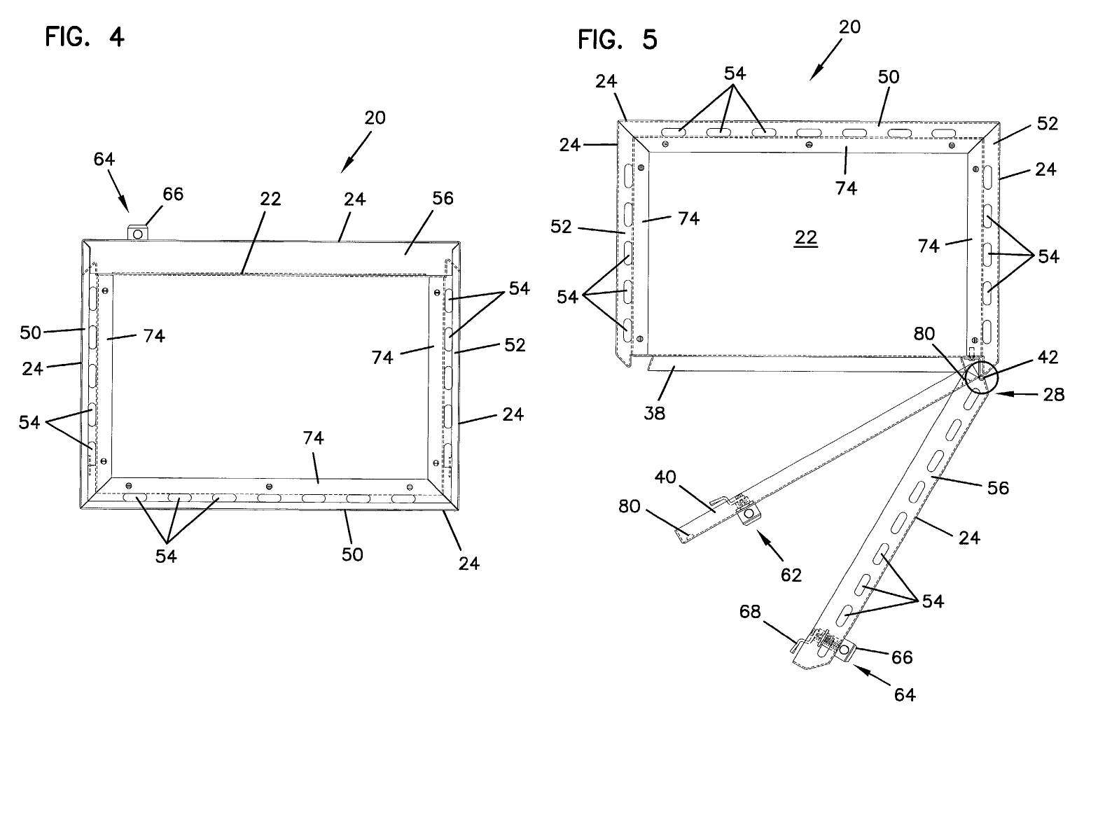

Referring to FIGS. 1-5, solar shielding 24 surrounds the front, back, sides and top of the enclosure to provide protection from exposure to the sun and prevent excessive heat in the inner enclosure 22. The solar shielding 24 provides a spaced apart wall that forms a ventilation space around the inner enclosure 22. The shielding 24 forms a passive cooling system that helps to maintain the inner enclosure 22 at a lower temperature and protects the equipment housed therein.

The shielding 24 includes modular components forming a shield, including a top shielding element 48, a rear shielding element 50, side shielding elements 52 and an outer door, which functions as shielding element 56. The various shielding elements are double-walled and may include ventilation holes 54 to improve circulation while also preventing pests and other debris from entering or becoming lodged in the ventilation space. With a modular configuration, shielding may be optimized for various size enclosures with the present system by mixing and matching shielding elements. Both side elements 52 mount to the inner enclosure 22 with mounting flanges 74 while the rear shielding element 50 mounts to the inner enclosure 22 with flanges 74. The various flanges extend over the top and the bottom of the enclosure to receive mounting hardware and maintain alignment. The top shielding element 48 mounts over the other elements and overlaps the other elements to provide continuous spaced apart shielding 24. The shielding 24 provides a thermal wrap covering all sides and the top of the inner enclosure. It can be appreciated that with such an arrangement, the system utilized for constructing the shielding portion 24 can be retrofitted to existing enclosures already in the field.

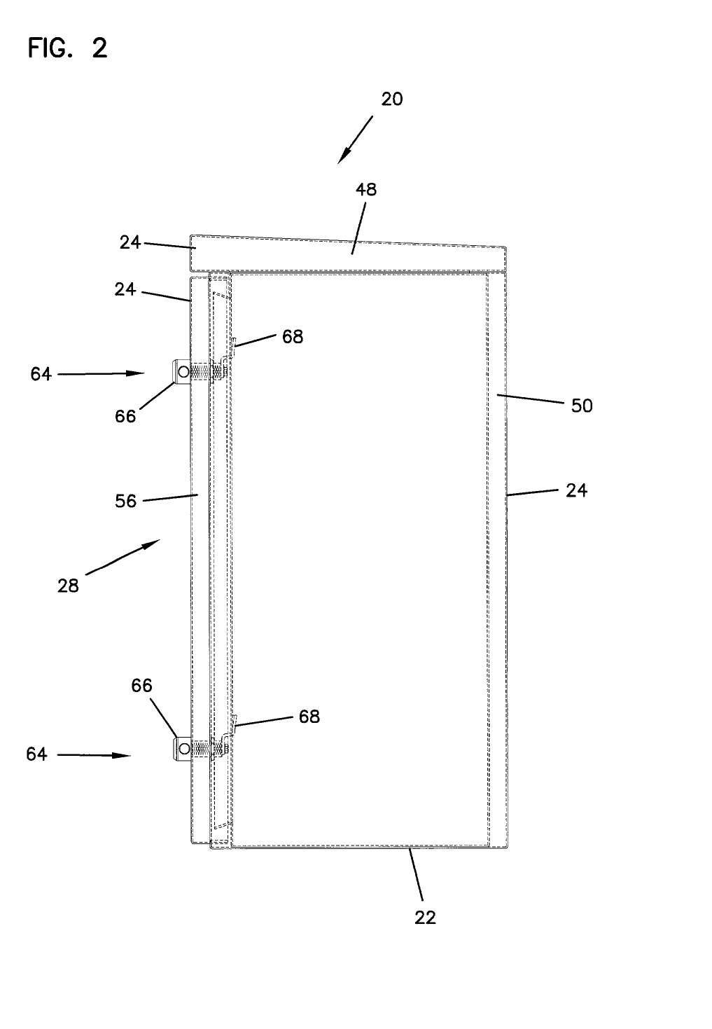

As shown most clearly in FIG. 5, the door assembly 28 mounts on a hinge 42 spaced apart from the walls of the inner enclosure 22. The positioning of the hinge 42 and its axis provides for improved pivoting of an inner door 40 and the outer shielding door 56 without scraping or swiping of gasket 80 against any of the other surfaces of the enclosure 20. When the inner door 40 is closed, the gasket 80 seals against a lip 38 extending around the opening to the enclosure 20. The door assembly 28 may include a first latch 62 on the inner door and a second latch 64. The latches 62 and 64 may include a retainer 68 and a tool actuated or key actuated opening cylinder 66 mounted thereto. With such a configuration, various degrees of security may be added and changed, depending on the needs of the application. For some applications, it would be necessary only to view the components. In such applications, a first degree of security may be added by allowing only certain persons viewing access to the enclosure by looking through the inner door 40, which may be glass or other transparent material. Other persons may be given greater access and allowed to open the inner latch 62 and the inner door 40 and access the interior of the inner enclosure 22. As shown most clearly in FIGS. 1 and 2, multiple latches may be mounted to the door assembly 28 for improved latching along the outer end of the doors. It will also be appreciated that one latch may include an added security measure so that various degrees of access to the inner enclosure 22 or just access to the inner door 40 may be achieved.

As shown in FIG. 5, the outer door 56 includes an angled end portion proximate the hinge 42. An angled end portion is also formed on the side shielding elements 52. With such angling, the outer door 56 may be opened to a larger degree than is possible with the prior designs and provides the advantages of not swiping the gasket 80 against the enclosure surfaces during opening and closing due to the position of the spaced apart hinge 42. In the embodiment shown, the outer door enclosure 56 may be opened to approximately one hundred twenty degrees. The inner door 40 may be opened to the same degree as the outer door 56, pressing against the outer door 56. Referring to FIG. 1, a doorstop 70 may be mounted on the inner door 40 to hold the inner door 40 and outer door 56 in the open position. This allows workers to access the components in the inner enclosure 22 without the door closing or having to hold the door assembly 28 at an open position. The doorstop 70 maintains the door assembly 28 at the open position even in outdoor applications, where wind and imbalance may tend to close the door assembly 28.

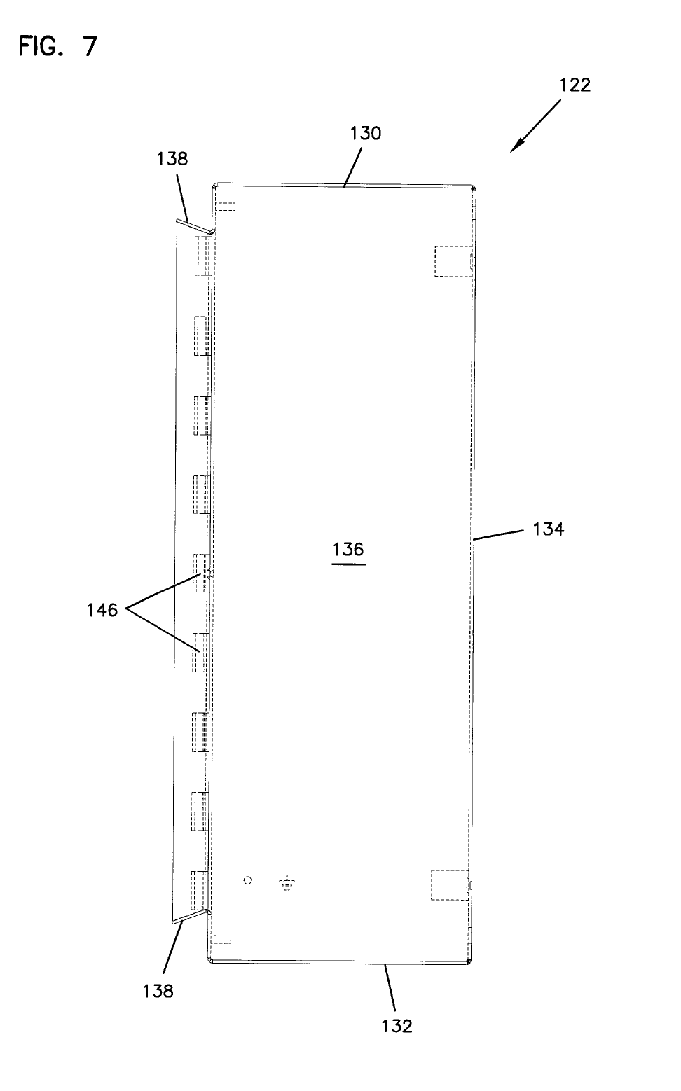

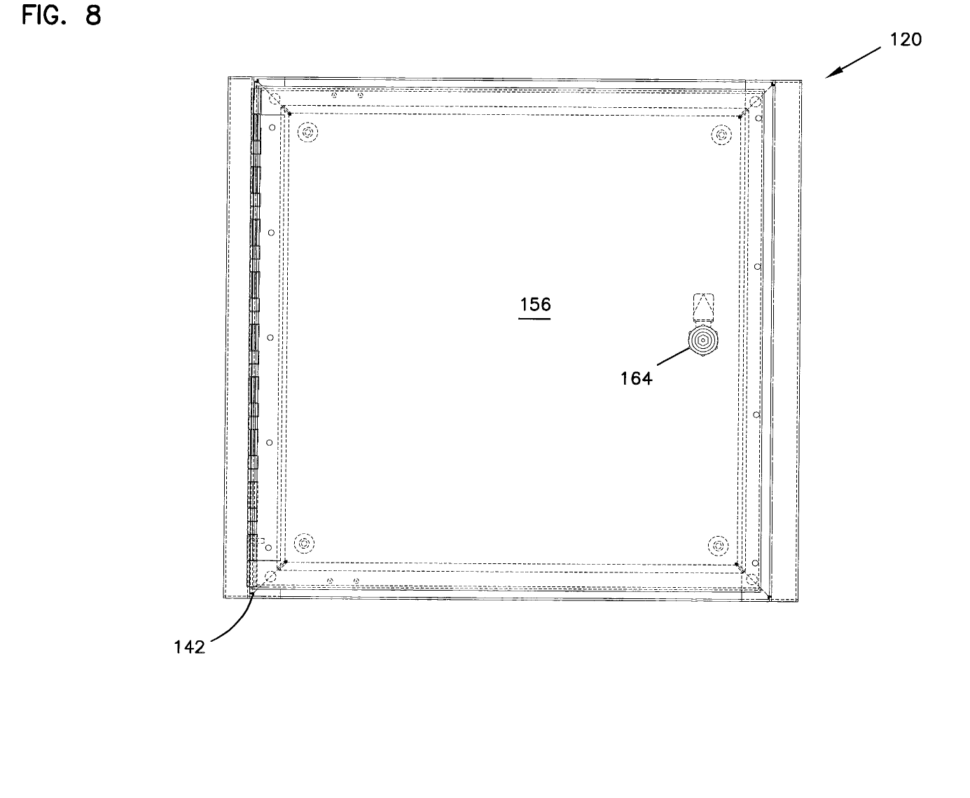

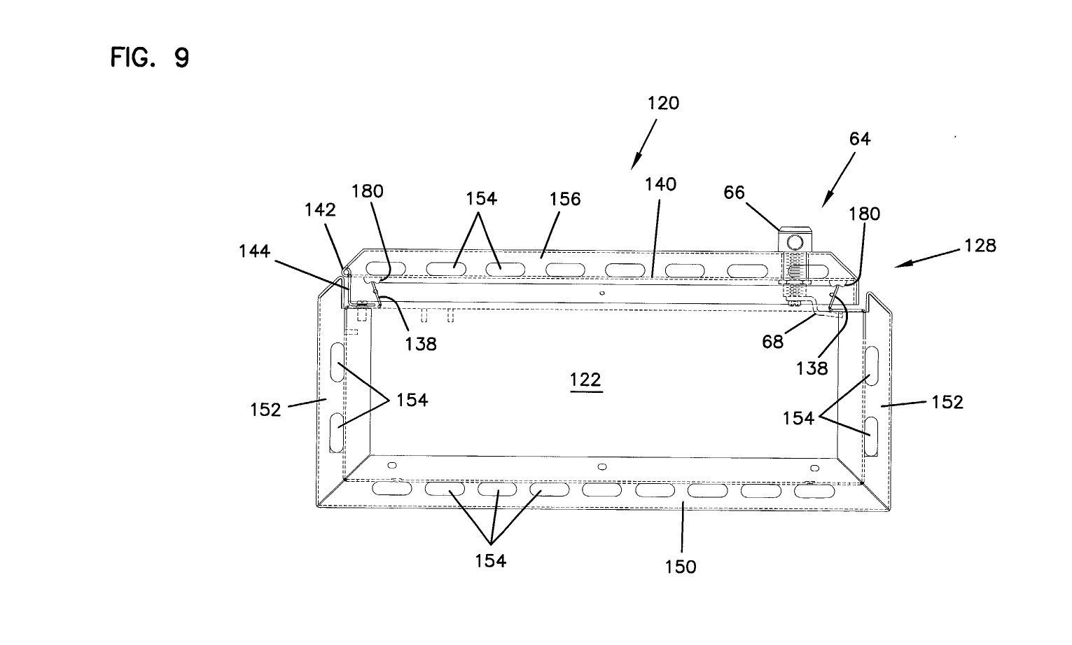

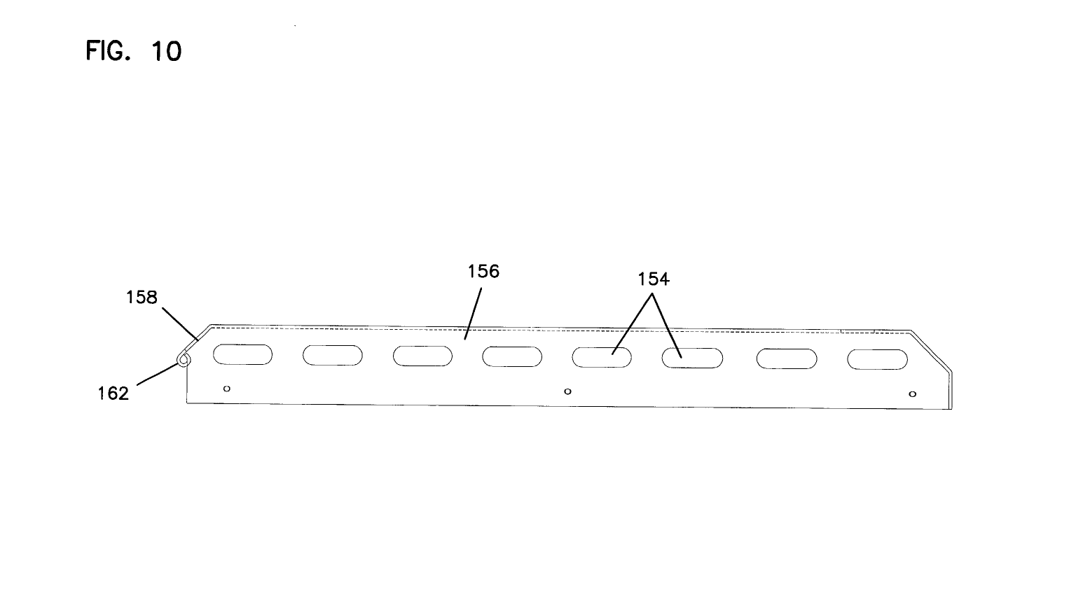

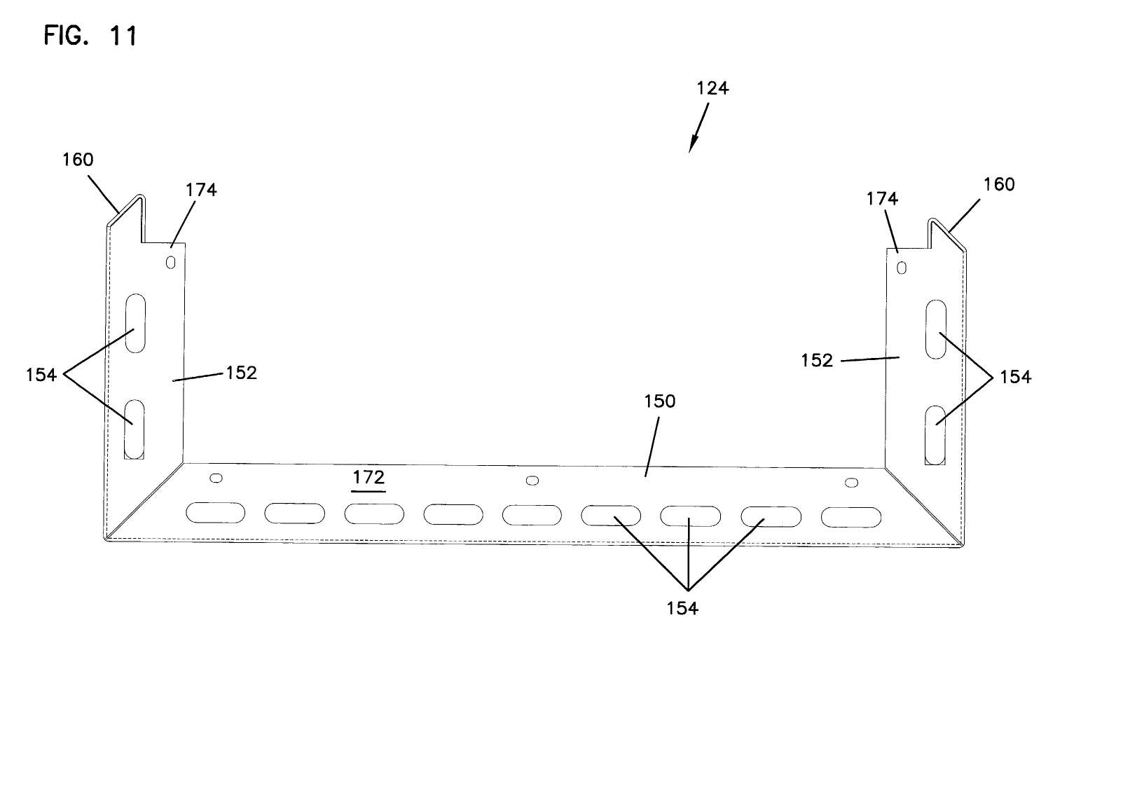

Referring now to FIGS. 6-11, there is shown a second embodiment of a shielded enclosure, generally designated 120 and similar to enclosure 20, described above. An inner enclosure 122 includes a top 130, bottom 132, back 134, and sides 136. A lip 138 extends around the periphery of the opening for improved opening and sealing. One edge of the lip 138 includes knuckles 46 for a hinge 142 as explained below. As shown in FIGS. 6 and 7, the inner enclosure 122 for the shielded enclosure 120 is shown. As explained above, the inner enclosure 122 is sized for the particular application. Referring to FIGS. 8 and 9, the shielded enclosure 120 is similar to the shielded enclosure 20. The shielded enclosure 120 includes a single latch 164, rather than multiple latches. The shielded enclosure 120 includes a top shielding element, and as shown in FIG. 9, shielding elements 150, 152 and 156. Ventilation holes 154 provide for improved circulation around the inner enclosure 122 and cooling. The shielding elements 150 and 152 include angled complementary end portions for improved fit around the inner enclosure 122. In addition, the hinge 142 is spaced apart from the inner enclosure 120.

A door assembly 128 of the outer door enclosure 156 includes an angled end cooperating with an angled end of the side shielding element 152 to provide for an improved pivoting range so that the door 128 may open to at least 120 degrees. As both ends of the outer door enclosure 156 are angled and the side elements 152 include angled ends, the shielding system provides interchangeability so that the door assembly 128 may be opened in either direction with the same parts. In addition, the hinge 142 is spaced apart on an angled mount 144 that may be mounted along either edge of the inner enclosure 122 to provide for improved opening and sealing without swiping of gasket 180 against any of the other components. The latch 64 includes an actuator 66 that may take on various embodiments for the required level of security and a retainer 68 cooperating with the actuator 66 and engaging the inside of the inner enclosure underneath the lip 138.

Referring to FIG. 11, the side elements 152 and rear element 150 may be assembled prior to the mounting to the inner enclosure. The assembly may simply be slid onto and over the rear of the inner enclosure with flange portions 172 and 174 sliding over the top 130 along the inner enclosure 122. This arrangement helps to guide and align the shielding and the inner enclosure 122 for improved fit. Moreover, the angled end portions 160 provide for opening the door assembly 128 in either direction. The shielding assembly 124 may also be assembled one piece at a time and may be utilized to retrofit to existing enclosures.

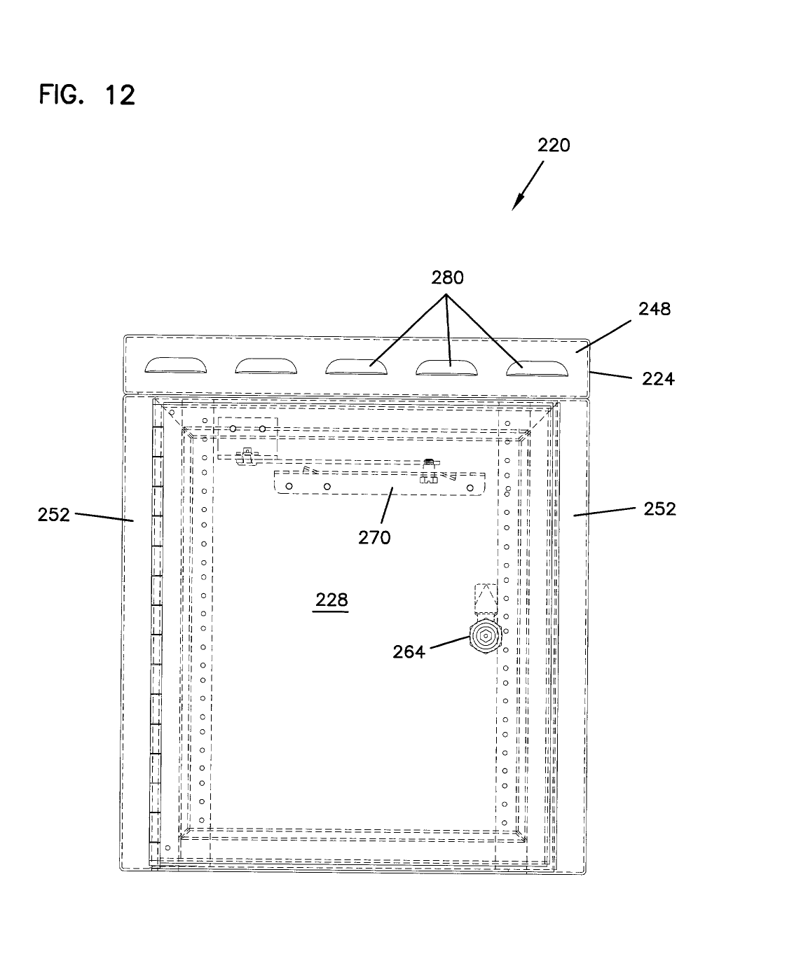

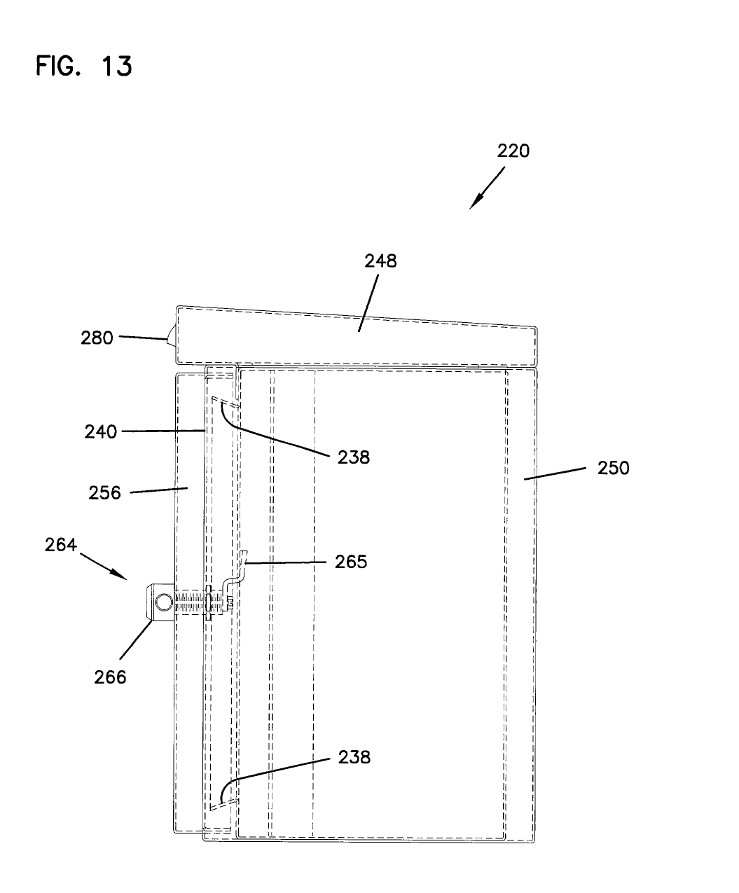

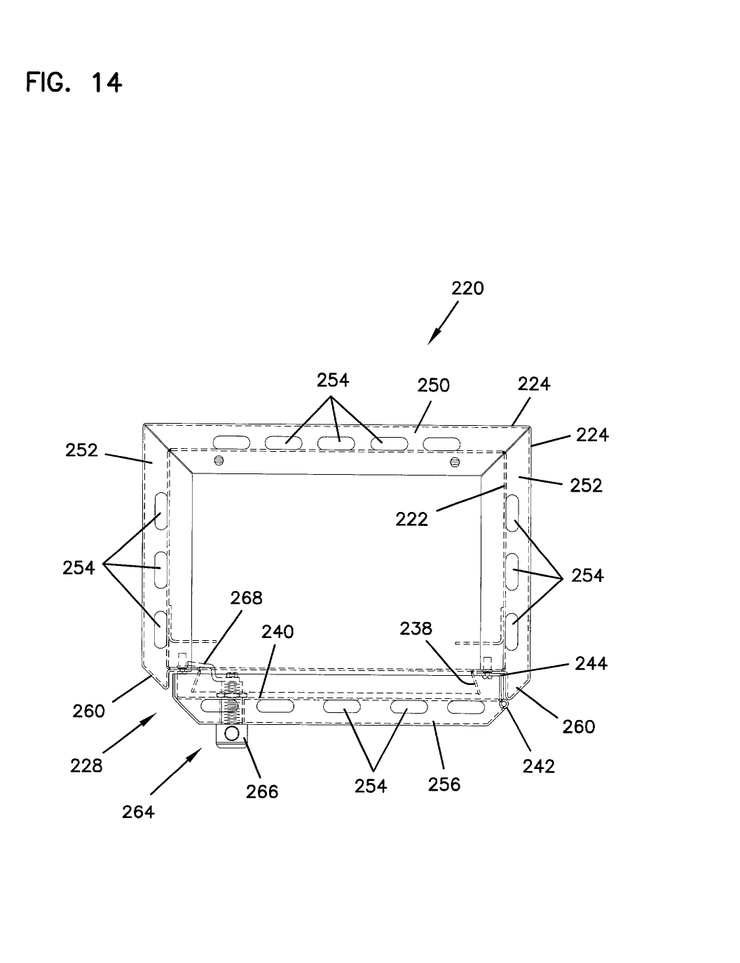

Referring now to FIGS. 12-14, there is shown a third embodiment of a shielded enclosure, generally designated 220. The shielded enclosure 220 includes an inner enclosure 222 with outer solar shielding forming enclosed solar shield 224. The solar shield 224 includes a top shielding element 248. The top shielding element 248 includes an angled upper surface to aid in shedding rain, snow and debris, and also includes side louvers 280. The louvers 280 improve airflow into and out of the top element 248. In addition, rear element 250 and side elements 252 wrap around the inner enclosure 222, as shown most clearly in FIG. 14. The elements 250 and 252 typically include ventilation holes 254 that improve circulation and airflow. An outer door enclosure 256 wraps around part of a door assembly 228. The door assembly 228 includes a hinge 242 spaced apart from the inner enclosure 222 mounted on an angled mounting element 244. The ends 260 of the side elements 252 are angled to cooperate with the angled ends of the outer enclosure 256 to provide an improved range of motion. A latch 264 has an actuator 266 and a retainer 268 wrapping around a lip 238 of the inner enclosure 222. The latch 264 may be actuated with different degrees of security for limiting and controlling access to the enclosure and providing different degrees of security and access to the enclosure 220. The door assembly 228 includes an inner door 240, which also pivots about the same hinge 242. The spacing of the doors 240 and 256 pivoting about the hinge 242 provides improved access and controlled access to the inner enclosure 222.

It is to be understood, however, that even though numerous characteristics and advantages of the present invention have been set forth in the foregoing description, together with details of the structure and function of the invention, the disclosure is illustrative only, and changes may be made in detail, especially in matters of shape, size and arrangement of parts within the principles of the invention to the full extent indicated by the broad general meaning of the terms in which the appended claims are expressed.

What is claimed is:

1. A double-walled solar shielding system for an electrical enclosure, comprising:
an inner enclosure having a first wall defining a substantially rectangular box;
an inner door pivotally mounted to the inner enclosure about a hinge;
a spaced apart shielding layer extending around the electrical enclosure top, rear and lateral sides; and
a shielding door mounted to the door hinge and having an outer layer spaced apart from the inner door.

2. A solar-shielded device according to claim 1, wherein the shield door and the enclosure door open independently.

3. A solar shielded device according to claim 1, wherein lateral edges of the shield door and lateral edges of the solar shield are angled obliquely to the opposed sides and to the enclosure door.

4. A solar-shielded device according to claim 1, wherein the enclosure door has a pivoting range of motion of at least 120 degrees.

5. A solar shielded device according to claim 1, wherein the hinge is spaced apart from an inner plane of the enclosure door, whereby the enclosure door rotates without wiping against the enclosure.

6. A solar-shielded device according to claim 1, wherein the shield door and the enclosure have separate security measures.

7. A solar shielded electrical enclosure device, comprising:
an enclosure, including a top, bottom, rear and opposed sides, an enclosure door mounted on a hinge;
a solar shield mounted to the enclosure, the shield including a shielding layer spaced apart from the enclosure at the rear, opposed sides and top to define a ventilation space proximate the enclosure;
a solar shield door mounted to the hinge and covering the enclosure door, including a shielding layer spaced apart from the enclosure door.

8. A solar-shielded device according to claim 7, wherein the shield door and the enclosure door open independently.

9. A solar shielded device according to claim 7, wherein lateral edges of the shield door and lateral edges of the solar shield are angled obliquely to the opposed sides and to the enclosure door.

10. A solar-shielded device according to claim 7, wherein the enclosure door has a pivoting range of motion of at least 120 degrees.

11. A solar shielded device according to claim 7, wherein the hinge is spaced apart from an inner plane of the enclosure door, whereby the enclosure door rotates without wiping against the enclosure.

12. A shielding system, comprising:
a shielding assembly configured for receiving an inner enclosure with an enclosure door, the shielding assembly having an outer layer spaced apart from the inner enclosure with lateral portions extending inward, the shielding assembly having opposed sides, a top and a rear;
a covering door mounted to the shielding assembly and configured for covering the enclosure door, the covering door having an outer layer with lateral portions extending inward configured to engage the enclosure door.

13. A double walled electrical enclosure, comprising:
an inner enclosure having an interconnected top wall, bottom wall, rear wall, and opposed side walls, forming a first chamber, a first door pivoting on a hinge attached to the inner enclosure;
an outer enclosure having a top layer, rear layer, an openable front layer, opposed side layers, and an open bottom, wherein the layers of the outer enclosure are spaced apart from the inner enclosure forming a conduit between the inner enclosure and outer enclosure.

14. An electrical enclosure according to claim 13, wherein the front layer comprises a second door co-axially pivoted with the first door.

15. An electrical enclosure according to claim 13, wherein the second door defines a conduit between the inner door and the outer door.

16. An electrical enclosure according to claim 13, wherein corner portions are obliquely angled, providing a range of rotation for the doors of at least 120 degrees.

17. An electrical enclosure according to claim 14, wherein the first door and the second door have separate security measures.

18. An electrical enclosure according to claim 14, wherein the first and second doors pivot about an axis spaced outward from an plane of an inner surface of the first door.

19. An electrical enclosure according to claim 13, further comprising a lip extending around a periphery of the opening defined by the inner enclosure.

20. An electrical enclosure according to claim 13, wherein the layers include a connecting portion extending inward to the inner enclosure and wherein the connecting portion includes circulation orifices formed therein.
